(19) United States
(12) Patent Application Publication
(10) Pub. No.: US 2009/0012727 A1
(43) Pub. Date: Jan. 8, 2009

(54) Detecting Partial Discharge in High Voltage Cables

(76) Inventors: Wah Hoon Siew, Glasgow (GB); John James Soraghan, Glasgow (GB); Ming Hui Foo, Glasgow (GB)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 11/817,749

(22) PCT Filed: Mar. 6, 2006
(86) PCT No.: PCT/GB2006/000798

§ 371 Date: Aug. 22, 2008

(30) Foreign Application Priority Data
Mar. 4, 2005 (GB) 0504600.8

(51) Int. Cl. G01R 31/11

(52) U.S. Cl. 702/59

(57) ABSTRACT

A method for detecting partial discharge events comprising analysing an output from the cable using one or more substantially shift invariant wavelet transforms, and using the analysed signal to identify one or more peaks associated with a partial discharge. Preferably, the shift invariant transform is a stationary wavelet transform (SWT).

The present invention relates to a system and method for detecting and locating partial discharges in high voltage cables, preferably underground cables.

Partial discharge is a phenomenon commonly known to the power industry. A partial discharge is defined as an electrical discharge in a gaseous medium, which does not normally lead to a complete flashover between metallic conductors. With reference to power cables, these partial discharges tend to occur in voids within the insulation material, thus partially bridging the insulation between the conductors. Recognition of this event is important because these discharges promote degradation of the insulation material. In the case of high voltage equipment, this can lead to a permanent breakdown. In the event of unforeseen breakdowns, huge financial losses may be incurred by power companies. Thus, many leading power companies and utilities need methods for continual monitoring and diagnostics to predict potential breakdown.

In cables, a partial discharge manifests itself as an impulse that has occurred somewhere along the cable. The partial discharge current pulse typically has a very short duration, for example in the range of 1 nanosecond to hundreds of nanoseconds, depending on the type of discharge and type of cable. It has a broadband frequency spectrum. For a power cable operating at fifty hertz, a partial discharge occurs when the voltage exceeds the partial discharge threshold voltage. Partial discharge events vary from cable to cable. Each discharge may vary in amplitude, shape and duration. There may also be more than one source of partial discharge in a cable, thereby adding to the complexity of the detection process.

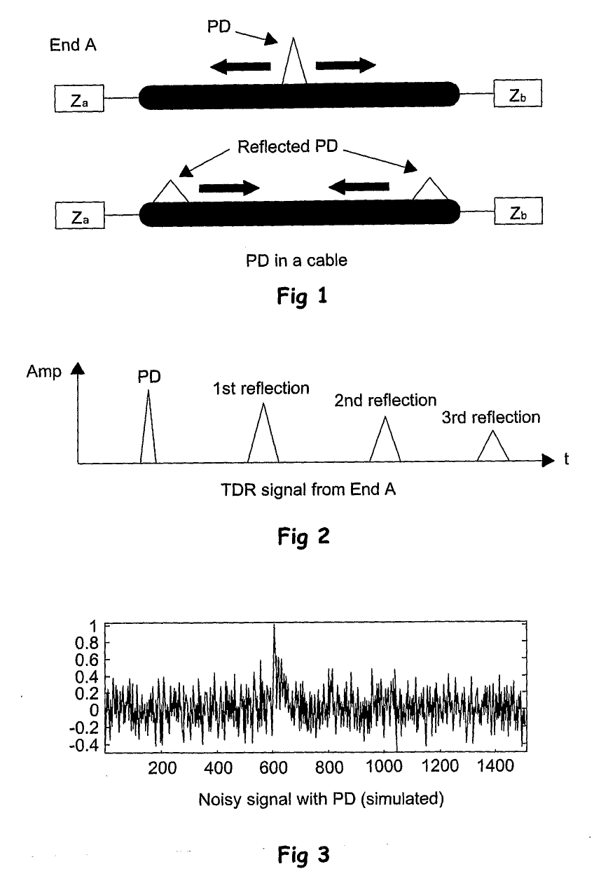

When a partial discharge occurs, the resultant impulse propagates along the cable in both directions, as shown in FIG. 1. The pulse then undergoes attenuation and dispersion due to the characteristics of the cable. When the propagating partial discharge pulse arrives at the end of the cable it is then reflected back in the opposite direction. The actual level of reflection depends on the impedance mismatch at the end of the cable, and hence determines the reflection co-efficient of the cable. If the cable has matched impedance, then there is no reflection.

One commonly known method of identifying the location of a partial discharge event uses time domain reflectometry (TDR). In this method, the time of arrival of the first and subsequent partial discharge current or voltage pulses is made at either end of the cable. In the simplest case, there is no other connection between the two ends of the cable. Usually variables such as the velocity of propagation and the length of the cable are known. Hence, the location of the partial discharge can be determined by evaluating the time duration between the first recorded pulse and the second recorded pulse, that is, the pulse that was reflected off the far end of the cable. An example of an ideal recording at one end of a cable is shown in FIG. 2.

The location of a partial discharge can be determined by evaluating the time difference between the first partial discharge pulse and the first reflected partial discharge pulse. From this time difference, a simple calculation can be used to calculate the distance from the measuring end of the cable to the partial discharge source. Where possible, this can be confirmed by using the second and third reflections, although it should be noted that whilst FIG. 2 shows these second and third reflections, in practice they may not be present due to signal attenuation.

Detection of partial discharges in cables can be classified as being either on-line or off-line. On-line techniques are conducted whilst the cable is energised. Off-line techniques are conducted when the cable is disconnected from the rest of the power system. One effective off-line technique for the detection and location of partial discharges uses a low frequency source, external to the main utility power supply, which is used to energise the cable after it has been disconnected. An example of this is described in the article “Diagnosing the Health of Your Underground Cable” by H. E. Orton, Transmission and Distribution World, June 2002. However, the requirement to disconnect the cable is a significant disadvantage, because it is very costly to the utility provider and also may cause further damage to weak points of the cable. There is therefore a need for an effective on-line method for detecting and locating partial discharges.

In both on-line and off-line techniques, acquiring partial discharge signals and synthesising them is not easy. However, this is particularly the case when dealing with on-line partial discharge acquisitions. High sampling rates are required to capture the high frequency content of the partial discharge signals. Inevitably, this content is captured along with noise that has been coupled into the circuit. Therefore, the raw partial discharge signals contain extra noise from radio interferences, switching circuits and random noise. A simulated example of a high pass filtered signal that is typically obtained from energised high voltage cables is shown in FIG. 3. Prom this it can be seen that the cable output is complex, with partial discharge reflection peaks being difficult to identify. Deriving useful information from this type of signal can be problematic.

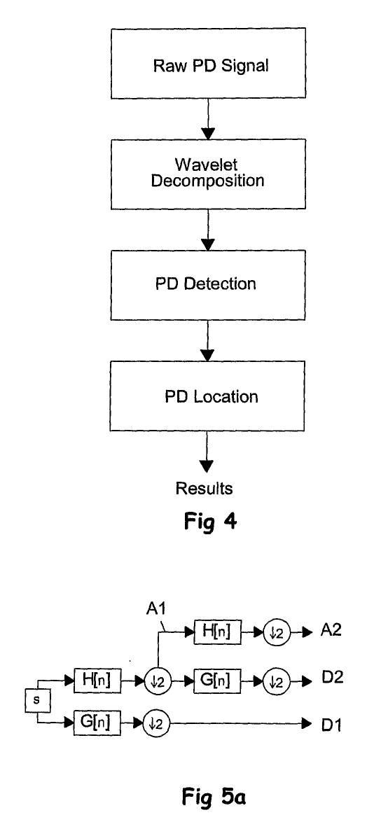

One well-known method of de-noising and analysing partial discharge data uses wavelets. Examples of this technique are described in the articles by Ma et al “Automated Wavelets Selection and Thresholding for Partial Discharge Detection” IEEE 2002, Vol. 18, No. 2 and “Interpretation of Wavelet Analysis and Its Application in Partial Discharge Detection” IEEE Transactions on Dielectrics and Electrical Insulation Vol. 9, No. 3, June 2002. Wavelet technique transforms raw partial discharge data and represents them in the time as well as frequency domain (the short hand notation of time frequency domain will be used from hereon). The signal is decomposed into a series of multi-scale signals that represent the partial discharge data. The partial discharge component, which has a narrow duration and a broadband frequency spectrum, exhibits its characteristics across all scales of the wavelet decomposition. To detect the origin of the partial discharge pulse, local maxima or signatures generated across the scales of the wavelet transform from the partial discharge event are observed. These can be used to detect the presence of a partial discharge. In addition, these local maxima or signatures can be used to determine the location of the source of the discharge, as shown in FIG. 4.

One specific wavelet transform that has been used for analysing partial discharge events is the decimated discrete wavelet transform, which is normally shortened to discrete wavelet transform (DWT). Examples of this technique are described in the articles “Digital Signal Processing Applied to the Detection of Partial Discharge: An Overview” by Shim et al, IEEE Electrical Insulation Magazine, May/June 2000, Vol 16, No. 3, and “Digital Signal Processing Applied to the Detection of Partial Discharge, Part 2: Optimised A/D Conversion” by Shim et al, IEEE Electrical Insulation Magazine, July/August 2000, Vol 16, No. 4. This is implemented by passing the signal acquired from a cable through a series of high pass and low pass filters, including a decimation process.

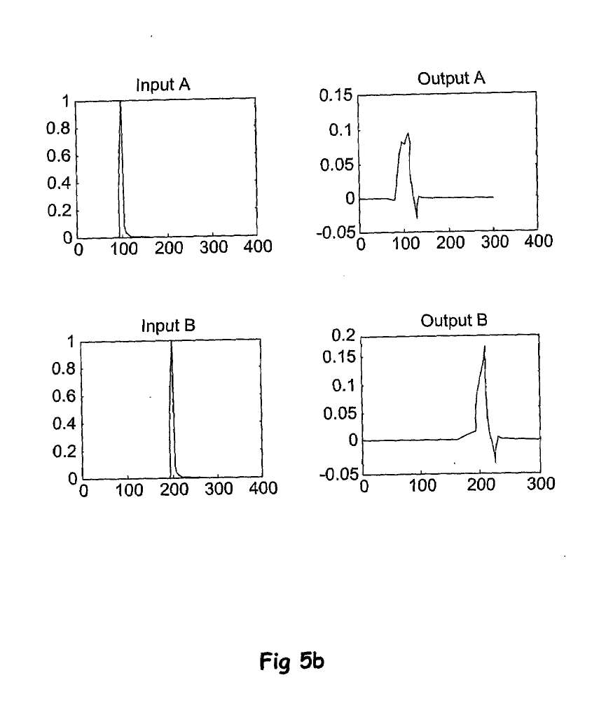

FIG. 5(a) shows a representation of a specific system for implementing a discrete wavelet transform. Whilst it is shown in block diagram form, it will be appreciated that it is implemented computationally. The transform of FIG. 5(a) has first and second parallel filters H(n) and G(n), through which the output signal from the cable is passed. The first filter, with coefficients H(n), is a low pass filter and the second filter, with coefficients G(n), is a high pass filter. The output from each filter is subsequently decimated by a factor of two. This means that the signal is divided into equal length sections and, for example, all the even sections are retained and all the odd sections discarded or alternatively all of the odd sections are retained and all of the even sections are discarded. This produces two decimated, decomposed signals, one of which is retained for analysis D1. The other one A1 of the decimated signals is filtered again using the same low and high pass filters H(n) and G(n) respectively as before. These filtered signals are then decimated, again in the same manner as described previously. This produces two decimated signals, one of which is retained for analysis D2, the other A2 being filtered again. This process is repeated. The maximum number of repetitions is log₂N, where N is the total number of data points in the signal. This produces a series of decomposed signals that can be inspected or analysed in order to identify the location of the partial discharge peaks.

The series of decomposed signals can used to reconstitute the original signal that can be inspected or analysed in order to identify the location of the partial discharge peaks. To do this, the decomposed signals are reconstituted to form the original signal by utilising the inverse low pass filters and high-pass filters, H(n)′ and G(n)′ of FIG. 5(a) respectively, whereby the steps chosen for the wavelet reconstitution are the reverse of wavelet decomposition, starting from the last wavelet decomposed signals, D2 and A2. Each of the wavelet-decomposed signals is firstly interpolated by a factor of two. This means that the signal is multiplied by two forming a length double that of the original wavelet decomposed signal length. For example a zero could be added before each sample in the wavelet decomposed signal, or alternatively a zero is added after each sample in the wavelet decomposed signal. The output of the interpolated wavelet decomposed signals is filtered with the inverse low pass filters and inverse high pass filters H(n)′ and G(n)′ respectively. The outputs of the inversed filters from D2 and A2 are then added together to produce the wavelet decomposed signal A1. This process is repeated until the original signal is reconstituted. Appropriate signal processing may be performed on the decomposed wavelet signals prior to reconstitution to obtain a better quality of the original signal. This decomposed, i.e. de-noised, and then reconstituted version of the signal can then be used to identify peaks.

Discrete wavelet transforms are computationally efficient and relatively easy to implement. However, despite much work in this field, discrete wavelet transform analysis has produced limited success in detecting and locating partial discharges in high voltage cables from on-line data. The inventors of the detection technique of the present application have realised that a significant problem with the use of discrete wavelet transforms in the analysis of partial discharge signals is that discrete wavelet transforms do not preserve shift-invariant properties. This means that for a single discrete wavelet transform a shifted version of an input signal does not produce a shifted version of the output.

FIG. 5(b) shows what is meant by the non-preservation of shift invariant properties. In this case, for a signal A that is input into a system/algorithm, the output produced is output A. Introducing a one hundred sample delay into signal A produces a new input signal, input B. The output signal for input B for the same system/algorithm is output B. From this, it can be seen that output B is not a shifted version of output A. Hence, the system/algorithm is said to be not shift invariant or the shift-invariant property is not preserved.

When applied to partial discharges, where the input signal may be continuously shifting with respect to time, the inventors have appreciated that non-preservation of shift invariance is a disadvantage.

An object of the present invention is to provide an accurate method for identifying and locating partial discharge events.

According to a first aspect of the present invention there is provided a method for detecting partial discharge events comprising analysing an output from the cable using one or more substantially shift invariant wavelet transforms, and using the analysed signal to identify one or more peaks associated with a partial discharge. By identifying peaks in the signal, a partial discharge event can be detected.

Preferably, the wavelet transform is non-decimated. The wavelet transform may be either a stationary wavelet transform or a combination of multiple decimated discrete wavelet transforms selected to produce a full non-decimated discrete wavelet transform.

Preferably, the wavelet transform is a stationary wavelet transform. By using a stationary wavelet transform to analyse the signal, the time location of the signal is preserved and the shape of the signal is substantially maintained. This means that it is easier to detect shift variances, and so improve the partial discharge detection rate, as well as the determination of the location of that partial discharge.

Stationary wavelet transforms are known. Examples are described in the article “The Stationary Wavelet Transform and some Statistical Applications” by Nason et al, Tech. Rep. BS81Tw, University of Bristol, 1995. and “Wavelet Toolbox—For use on Matlab” by Misiti et al, The Mathworks Inc, 2000. However, these have not previously been used to analyse signals from high voltage cables. Using these particular wavelet transforms provides unexpectedly good partial discharge detection rates.

Preferably, the method further involves identifying the location of the partial discharge using the peaks identified after de-noising using the stationary wavelet transform.

Alternatively, the method may involve identifying the location of the partial discharge using the peaks identified after de-noising using the stationary wavelet transform and after reconstituting the signal.

The method may be applied to stationary data. Equally, the method may be applied to non-stationary data.

According to another aspect of the present invention there is provided a computer program for detecting partial discharges in a high voltage cable, the computer program being preferably on a data carrier or a computer readable medium, and comprising code or instructions for analysing an output from the cable using one or more substantially shift invariant wavelet transforms, and using the analysed signal to identify one or more peaks associated with the partial discharge.

Preferably, the wavelet transform is non-decimated. The wavelet transform is either a stationary wavelet transform or a combination of multiple decimated discrete wavelet transforms selected to produce a full non-decimated discrete wavelet transform.

According to yet another aspect of the present invention there is provided a method for detecting partial discharge events comprising analysing an output from the cable using a stationary wavelet transform, and using the analysed signal to identify one or more peaks associated with the partial discharge.

Preferably, the method further involves identifying the location of the partial discharge using the peaks identified after de-noising using the stationary wavelet transform.

Alternatively, the method may involve identifying the location of the partial discharge using the peaks identified after de-noising using the stationary wavelet transform and after reconstituting the signal.

According to still another object of the invention there is provided a system for detecting partial discharge events, the system being configured to de-noise an output from the cable using one or more wavelet transforms that preserve one or more shift-invariant properties, and use the de-noised signal to identify one or more peaks associated with the partial discharge.

The system may be configured to acquire data from the cable in real time, so that the condition of the cable can be monitored. De-noising of the signal may be done at the same location as the data acquisition or may be done remotely therefrom.

Preferably, the wavelet transform is non-decimated. The wavelet transform is either a stationary wavelet transform or a combination of multiple decimated discrete wavelet transforms selected to produce a full non-decimated discrete wavelet transform.

Various aspects of the present invention will now be described by way of example only, and with reference to the accompanying drawings, of which:

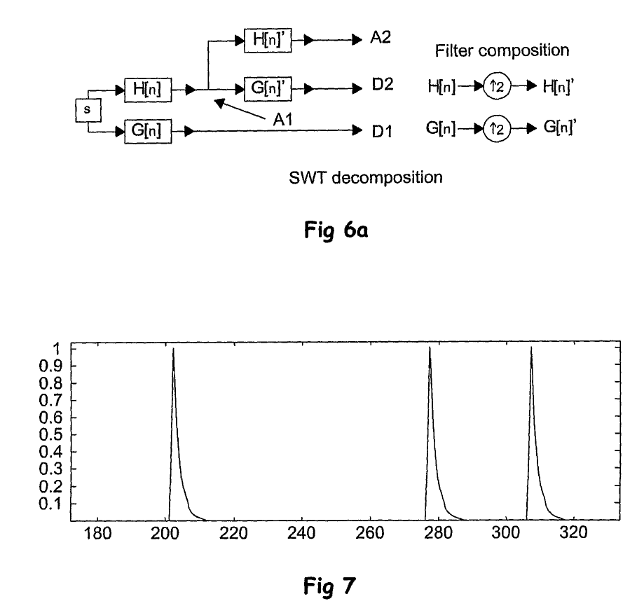

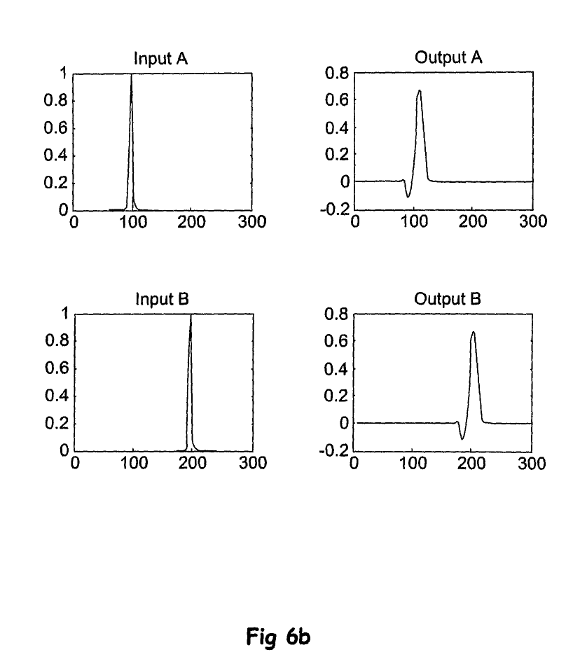

FIG. 6(a) is a diagrammatic representation of a system for implementing a stationary wavelet transform;

FIG. 6(b) shows various plots that demonstrate the shift invariant property of a stationary wavelet transform;

FIG. 7 is a simulated example of a signal detected at one end of a cable after a partial discharge event, in the absence of noise;

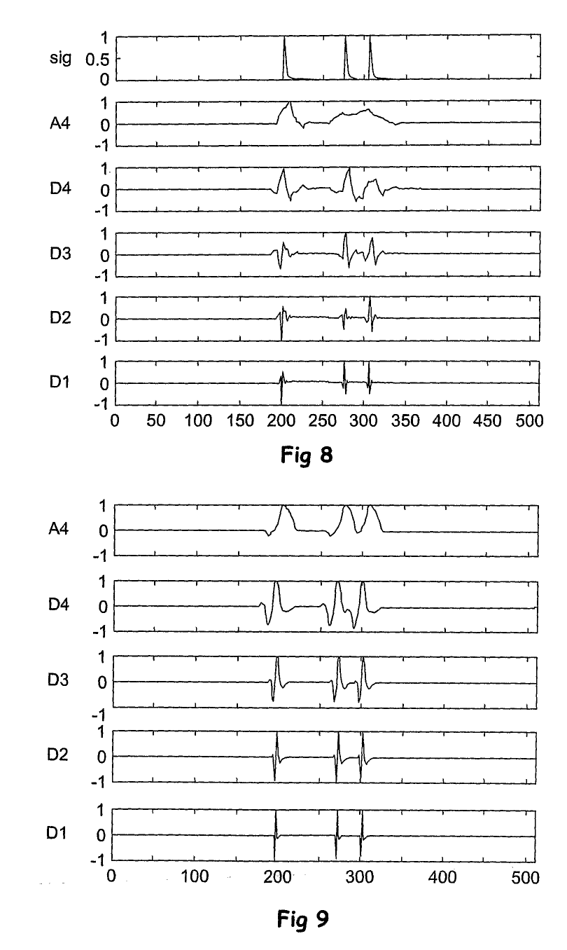

FIG. 8 shows simulated plots of decomposed components of the signal of FIG. 7 derived using a discrete wavelet transform;

FIG. 9 shows simulated plots of decomposed components of the signal of FIG. 7 derived using a stationary wavelet transform;

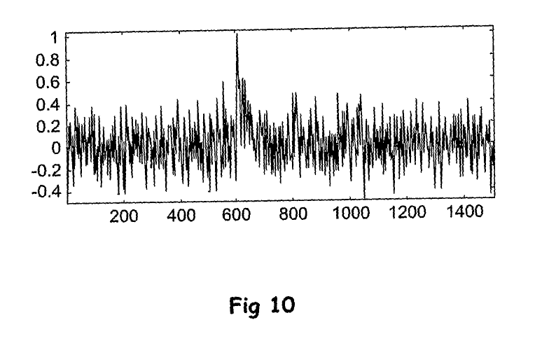

FIG. 10 is a simulated example of a signal detected at one end of a cable after a partial discharge event, in the presence of noise;

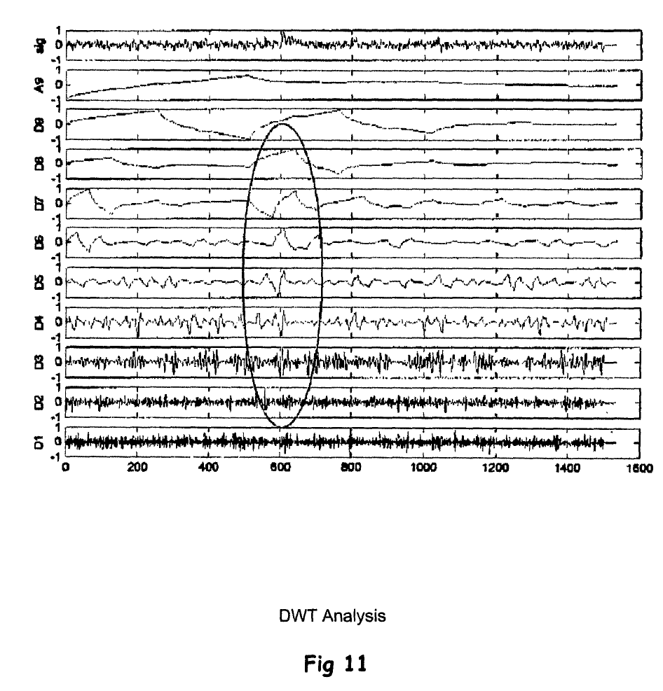

FIG. 11 shows simulated plots of decomposed components D1 to D9 and A9 of the signal of FIG. 10 derived using a discrete wavelet transform;

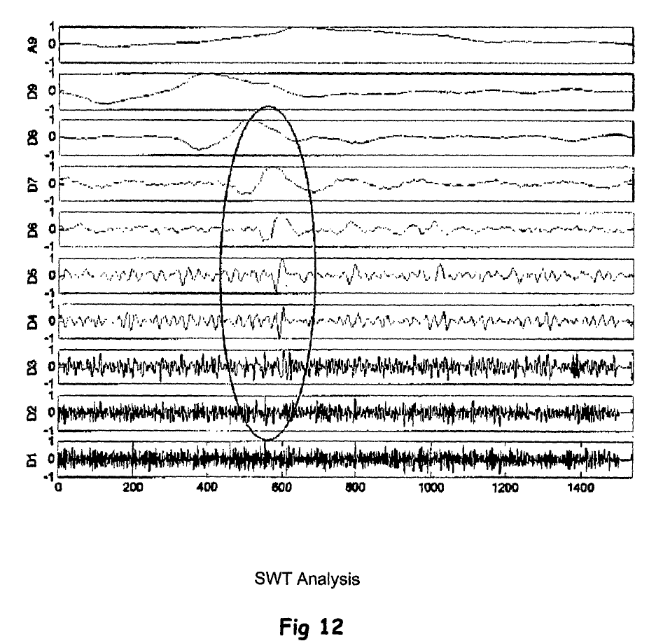

FIG. 12 shows simulated plots of decomposed components D1 to D9 and A9 of the signal of FIG. 10 derived using a stationary wavelet transform;

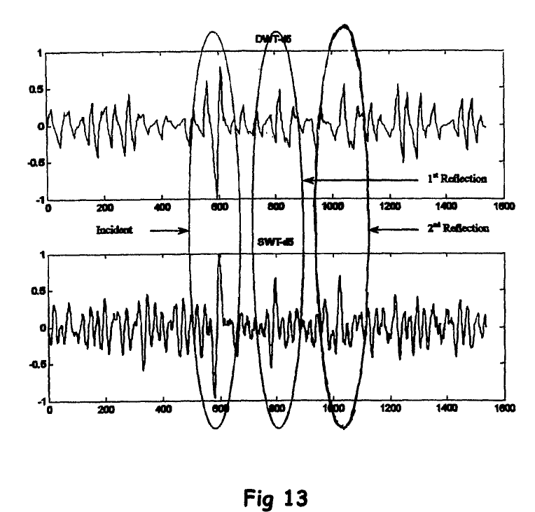

FIG. 13 shows a single decomposed component D5 from each of FIGS. 11 and 12;

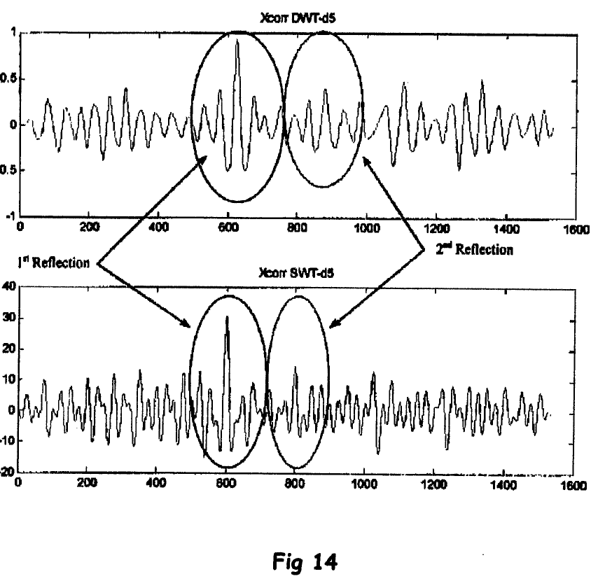

FIG. 14 shows a cross correlation of the components D5 of FIG. 13 and the initial partial discharge signature derived from these components, and

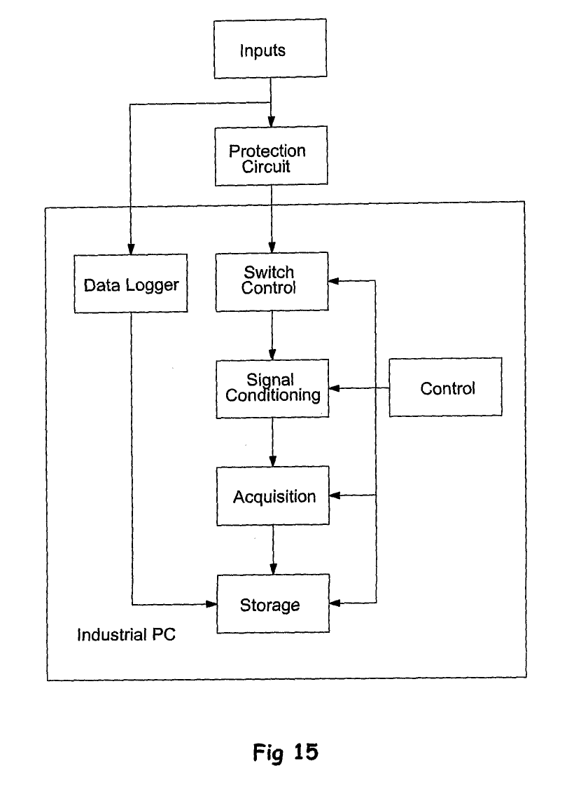

FIG. 15 is a block diagram of a data acquisition unit for monitoring signals at one end of a high voltage cable.

The system and method in which the present invention is embodied use a stationary wavelet transform in the wavelet decomposition stage of the process of FIG. 4. FIG. 6(a) shows the various process steps applied for this type of transform. In this case, the raw data from the cable is input into two parallel filters, a first one of these being a low pass filter H(n) and the other being a high pass filter G(n). However, in contrast to the methodology for discrete wavelet transforms, the output of these filters is not decimated. Because of this, the shift variance can be preserved. Instead, the output from the high pass filter G(n) is retained as the first decomposed component D1, and the output A1 from the low pass filter H(n) is applied to two modified low pass and high pass filters H(n)′ and G(n)′ respectively. Each of these modified filters H(n)′ and G(n)′ is generated by interpolating the initial filters H(n) and G(n) by a factor of two. To do this, zeroes are inserted between every coefficient of the original filter. The signal A1 is then filtered using these modified filters. The output D2 of the modified high pass filter G(n)′ is retained as a decomposed component. The output A2 of the modified low pass filter H(n)′ is, however, passed to two additional parallel filters, which filters are generated by modifying filters H(n)′ and G(n)′. In particular, and as before, these modified filters are generated by interpolating the filters H(n)′ and G(n)′. This process is repeated a number of times, thereby to produce a series of decomposed components Dₙ.

An advantage of using a stationary wavelet transform to analyse the signal is that it is shift invariant. By this is meant that for a shifted version of the input signal, the output produced is a shifted version of the original output. This is illustrated in FIG. 6(b), where input B is a one hundred sample delayed version of input A, and output B is a one hundred sample delayed version of output A. From FIG. 6(b), it can be seen that output B is merely a shifted version of output A.

To illustrate the differences in performance between the decomposition process using discrete wavelet transforms and stationary wavelet transforms, various simulations have been done. Daubechies-2 filters were used initially for the discrete wavelet transform and the stationary wavelet transform. FIG. 7 shows a simulated partial discharge signal, in the absence of noise. This is assumed to be an ideal exponential decaying pulse with a duration of ten samples. It is also assumed that the cable is ideal, so that there is no signal attenuation and no dispersion, with reflection coefficients of 100%. FIG. 8 shows the decomposed components D1 to D4 and A4 derived from a discrete wavelet transform of the signal of FIG. 7. FIG. 9 shows the decomposed components D1 to D4 and A4 derived from a stationary wavelet transform. From these plots, it can be seen that the shape of the partial discharge signal is better preserved for the stationary wavelet transform results than for the discrete wavelet transform results. Hence, the stationary wavelet transform provides more robust signatures.

Of course, in practice, for on-line data acquisition techniques, the signal received at the end of a high voltage cable would not be noise free, but instead is likely to be very noisy. FIG. 10 shows a simulated signal received at one end of a high voltage cable. This simulation was generated on the assumption that attenuation along the cable is very small, pulse dispersion does not occur and reflection only occurs at the end of the cable. The noise included in the simulated signal of FIG. 10 is very similar to that experienced in real environments. More specifically, the noise comprises a narrowband noise and random noise. The narrowband noise is simulated radio frequencies at 200 kHz, 600 kHz, and 800 kHz. A significant level of noise was added to the signal. Despite the inclusion of a significant level of noise in the simulated signal, even in these circumstances, using a stationary wavelet transform greatly improved the detection and location possibilities.

FIG. 11 shows the decomposed components D1 to D9 and A9 derived from a discrete wavelet transform based decomposition of the signal of FIG. 10, and FIG. 12 shows the decomposed components D1 to D9 and A9 derived from a stationary wavelet transform based decomposition. From these, it can be seen that partial discharge peaks can be identified—these are circled. This identification process can be done merely be visual inspection of the various components or alternatively using a suitable algorithm. To identify reflection signals, a segmented cross correlation is performed between the detected shape of the partial discharge impulse and the rest of the signal. To do this, the partial discharge pulse is detected. Then the duration of the partial discharge signature is determined and segmented. This is done for the predominant scales of the wavelet decomposition, i.e. for each of the decomposed signals D2 to D8 of FIGS. 11 and 12. In practice, due to the predominant noise in D1 and poor resolution in A9, they are not used for analysis. Next, a cross correlation between the segmented partial discharge signal is performed for one or more of the decomposition scales D2 to D8. In theory, whenever a segment of the scale has a reflection, a similar partial discharge signature should be detected, that is the reflected signals should have substantially the same shape as the initial discharge signal. Hence, by comparing the shape of the initial partial discharge with each portion of the signal of one or more of the decomposition scales, it should be possible to identify the reflected pulses. Once this is done, the time duration between the first pulse and the reflected pulse can be established and so the location of the partial discharge event can be determined.

FIG. 13 shows detailed views of the decomposed signal D5 for each of the discrete and stationary wavelet transforms. From this, it can be seen that there are three clearly distinguishable signatures for each case in the region of 600, 800 and 1000 samples. These signatures are generated by the partial discharge pulse from the incident pulse, and the first and second reflections. The first one of these, that is the signature at around 600 samples, is defined as the partial discharge signature to be used in the segmented cross correlation. The segmented cross correlation is used to compare the partial discharge signature across the entire signal. In the segmented cross correlation of the decomposed signals, a more accurate measure of the location of the reflected signals can be determined. The results of this for each of the discrete and stationary wavelet transforms are shown in FIG. 14.

To locate the partial discharge in the cable, the durations between the first and second pulse of each plot of FIG. 14 are determined. For the discrete wavelet transform data, the sample difference between the first and second peaks was found to be 257. This corresponds to a partial discharge location of 1.43 km from the end of the cable. For the stationary wavelet transform data, the sample difference between the first and second peaks was found to be 199 and the sample difference between the first and third peaks was found to be 422. This corresponds to a partial discharge location of 2.01 km from the end of the cable. In fact the actual location of the partial discharge was 2 km from the end of the cable. Hence, by using the stationary wavelet transform data, the location of the discharge can be estimated to within ten metres of the actual location. This is advantageous.

By using a wavelet transform that preserves the shape of the partial discharge pulse, and in particular a stationary wavelet transform, partial discharge diagnostics can be performed with better efficiency. In practice, this means that despite the well-documented problems with noise, on-line monitoring and diagnostics of such cables becomes an attractive option. FIG. 15 shows a suitable on-line data acquisition unit that could be used for such on-line measurements.

The data acquisition unit of FIG. 15 is implemented on a PC mounted in a weatherproof-shielded box. The data acquisition unit performs the acquisition of partial discharge signals from the cable circuits under online conditions. It is adapted to be connected to the output of current transformers or other auxiliary cable terminations of the 3-phase circuit of the power cable that is to be monitored. These cable terminations have to have a wide bandwidth and high frequency response to facilitate transient and partial discharge detection. In total, there are three outputs from the three phase cable terminations fed into the data acquisition unit. When a partial discharge occurs, the current pulse propagates along the cable towards the terminations of the cable. The arrival of the partial discharge pulse at the cable terminations is detected and coupled into the data acquisition unit.

The data acquisition unit is connected to the cable via a protection circuit or devices. This is needed because the unit is on-line and so has to have a permanent connection to the cable for the period of observation and data acquisition. In the event of surge over voltage or fault in the data acquisition unit, the protection circuit acts as a safety buffer between the data acquisition unit and the cable. If a fault occurs on the unit, this would avoid the protection mechanism of the substation from being activated. Any suitable protection circuit can be used. However, as will be appreciated, the specific design depends on the nature of the power network to which the data acquisition unit is to be connected.

Connected to an output from the protection circuit is the data acquisition unit and in particular a switch control section that has a software-controlled switch for selecting the desired phase(s) of acquisition. The measurements can be classified into two categories, i.e. single or dual phase. In single-phase measurements, the switch is programmed to select one of the three phase inputs for acquisition. For dual phase measurements, two phases out of the three phase inputs are selected. The chosen signal is then fed into a signal-conditioning unit. The signal-conditioning unit comprises a band pass filter that has a bandwidth of 100 kHz to 30 MHz. It is electronically controlled, and so the choice of band pass window size is adjustable and can be modified according to the desired window size. The purpose of this section is to enable the user to select any particular bandwidth of the signal for partial discharge analysis or noise analysis. This is an important feature, because it allows a robust selection of narrowband detection or wideband detection for enhancing the PD analysis or noise rejection.

The output from the signal conditioning section is connected to an acquisition section. This consists of a high-speed analogue-to-digital converter card within the PC. It has a maximum sampling rate of 100 Msamples/sec on a single channel and 50 Msamples/s on dual channel mode, with a 14 bit resolution. High sampling rates are required together with a reasonably good resolution to capture the effects of the PD signal. In this case, the acquired signal can have content up to a maximum of 50 MHz for the single channel mode. This is advantageous for time domain reflectometry (TDR) purposes, because it provides a balance of good time and amplitude resolution. Any suitable analogue-to-digital converter card can be used, but as a preferred option the card has at least 8 Mbytes of onboard buffer memory. At high sampling rates, this allows the continuous acquisition of data until the complete buffer is filled, then it is dumped into a storage unit. At low sampling rates, long continuous acquisition of data can be performed, usually for statistical analysis.

When the ADC buffer is filled, the data is stored into the hard disk of the PC in binary format. The filenames of the data are stored in a systematic method to provide identification to the acquisition settings. The unit has one designated removable hard disk drives installed. This allows its retrieval by delegated authorised personnel. It is estimated that with a 40 Gbytes capacity hard drive, 400 seconds of PD data is available (acquired at 50 MS/s).

The data acquisition unit is controlled by central control software that can be operated on-site or remotely. For the remote connection a GSM modem is used as the means of the remote communication device. The remote user is allowed to perform a connection through a dial up system, with a secured authorisation access. The software runs under a layer of TCP/IP communication modules. When the connection is established, the acquisition unit enables the user to insert or modify all the acquisition parameters on the system, for instance the sampling rates and the selection of circuits. The system is programmed to store reports and log files that are automatically sent back to the remote user. Using this unit enables the user to program acquisition parameters either on site or remotely.

The binary data files saved by the acquisition unit are primarily analysed under the Matlab environment. Therefore, for certain types of analysis, the acquisition parameters have to be set to provide the necessary required data. For example, in the partial discharge statistical analysis the observation of the partial discharge characteristics i.e. amplitude, repetition rates, phase location, partial discharge pulse shapes, requires a continuous sequenced multiple cycle of partial discharge data. Thus, the sampling rate of the acquisition unit can be set to a lower value in order to fulfil the requirements.

In addition to the above component, the data acquisition unit of FIG. 15 includes a current data logger. The data logger is connected between an input of the data protection circuit and the storage unit and is provided to facilitate the analysis of the relationship between the line current and partial discharge activity. The effects of current loading are taken into consideration by monitoring the line current and its loading conditions. For this purpose, the current on one phase of the circuit is sufficient. To this end the current data logger has a current transducer (not shown), which is connected to one of the inputs to the unit. The transducer is normally a clip-on current probe, and hence does not require protection. The line current can be monitored at pre-determined time intervals and stored in the hard drive of the PC.

In use, the data acquisition unit is connected to a cable, and signals passing along the cable are monitored. Data can be accumulated over days and weeks, depending on the user defined frequency and quantity of data acquisition. Once obtained, the data is analysed by firstly using stationary wavelet transform as previously described. This provides one or more decomposed signal components, each of which is inspected to determine the initial partial discharge signature. This is then cross-correlated with one of the decomposed signals, thereby to determine the location of one or more reflected signals. The location of these reflected signals can be used to estimate the physical location of the partial discharge in the cable.

In the specific example shown in and described with reference to FIG. 15 data analysis is done remotely from data acquisition. However, the data acquisition unit optionally could be equipped with pre-processing capabilities for on-site signal analysis, if required. This would give the utility provider an immediate on-site indication of any potential faults caused by one or more partial discharges.

The system and method in which the invention is embodied provide an improved technique for detecting and locating partial discharges in high voltage cables. This has significant technical and commercial advantages.

A skilled person will appreciate that variations of the disclosed arrangements are possible without departing from the invention. For example, whilst the invention has been described with reference to high voltage utility cables, partial discharges from the windings of power transformers may be also detected and located using these techniques. The windings of such power transformers may be considered as one long cable having been wound many times round an iron former.

Furthermore, whilst the description has described identifying peaks using the SWT decomposed signal, this could instead be done using a version of the signal re-constituted after the stationary wavelet transform decomposition. To do this, several methods could be used. This is further described in the article, “The Stationary Wavelet Transform and some Statistical Applications” by Nason et al, Tech. Rep. BS81Tw, University of Bristol, 1995. One method of reconstituting the original signal from the wavelet decomposed signals involves using the inverse low pass filter and the high pass filter, H′(n) and G′(n) i.e. the first stage of wavelet decomposition of FIG. 6(a) respectively. The steps chosen for the wavelet reconstitution are the reverse of wavelet decomposition, starting from the last wavelet decomposed signals, D2 and A2. The outputs of the inverse filters from D2 and A2 are added together to produce the wavelet decomposed signal A1. Then process is repeated with the modified inverse low pass filter and modified inverse high pass filter. Again here the filters are generated by interpolating the inverse filters H′(n) and G′(n). This process is repeated until the original signal is reconstituted. Appropriate signal processing may be performed on the decomposed wavelet signals prior to reconstitution to obtain a better quality of the original signal. The signal processing may be common de-noising methods, which can be applied to the wavelet decomposed signals before obtaining the reconstituted version of the signal that can then be used to identify peaks.

Accordingly, the above description of a specific embodiment is made by way of example only and not for the purposes of limitation. It will be clear to the skilled person that minor modifications may be made without significant changes to the operation described.

1. A method for detecting partial discharge events comprising analysing an output from the cable using one or more substantially shift invariant wavelet transforms, and using the analysed signal to identify one or more peaks associated with a partial discharge.

2. A method as claimed in claim 1 wherein the wavelet transform is non-decimated.

3. A method as claimed in claim 1 wherein the wavelet transform is a stationary wavelet transform or a combination of multiple decimated discrete wavelet transforms selected to produce a full non-decimated discrete wavelet transform.

4. A method as claimed in claim 1 comprising identifying the location of the partial discharge using the peaks identified after de-noising using the stationary wavelet transform.

5. A method as claimed in claim 4 comprising identifying the location of the partial discharge using the peaks identified after de-noising using the stationary wavelet transform and after reconstituting the signal.

6. A computer program for detecting partial discharges in a high voltage cable, the computer program being preferably on a data carrier or a computer readable medium, and comprising code or instructions for analysing an output from the cable using one or more substantially shift invariant wavelet transforms, and using the analysed signal to identify one or more peaks associated with the partial discharge.

7. A computer program as claimed in claim 6 wherein the wavelet transform is non-decimated.

8. A computer program as claimed in claim 6 wherein the wavelet transform is a stationary wavelet transform or a combination of multiple decimated discrete wavelet transforms selected to produce a full non-decimated discrete wavelet transform.

9. A computer program as claimed in claim 6 comprising code or instructions for identifying the location of the partial discharge using the peaks identified after de-noising using the stationary wavelet transform.

10. A computer program as claimed in claim 9 comprising code or instructions for identifying the location of the partial discharge using the peaks identified after de-noising using the stationary wavelet transform and after reconstituting the signal.

11. A method for detecting partial discharge events comprising analysing an output from the cable using a stationary wavelet transform, and using the analysed signal to identify one or more peaks associated with the partial discharge.

12. A method as claimed in claim 11 involving identifying the location of the partial discharge using the peaks identified after de-noising using the stationary wavelet transform.

13. A method as claimed in claim 11 involving identifying the location of the partial discharge using the peaks identified after de-noising using the stationary wavelet transform and after reconstituting the signal.

14. A system for detecting partial discharge events, the system being configured to de-noise an output from the cable using one or more wavelet transforms that preserve one or more shift-invariant properties, and use the de-noised signal to identify one or more peaks associated with the partial discharge.

15. A system as claimed in claim 14 that is configured to acquire data from the cable in real time, so that the condition of the cable can be monitored.

16. A system as claimed in claim 14 wherein the wavelet transform is non-decimated.

17. A system as claimed in claim 14 wherein the wavelet transform is a stationary wavelet transform or a combination of multiple decimated discrete wavelet transforms selected to produce a full non-decimated discrete wavelet transform.
